(19) United States
(12) Patent Application Publication
(10) Pub. No.: US 2024/0097031 A1
(43) Pub. Date: Mar. 21, 2024

(54) FERRORELECTRIC FIELD-EFFECT TRANSISTOR (FEFET) DEVICES WITH LOW OPERATING VOLTAGE CAPABILITIES

(71) Applicant: Intel Corporation, Santa Clara, CA (US)

(72) Inventors: Punyashloka Debashis, Hillsboro, OR (US); Rachel A. Steinhardt, Beaverton, OR (US); Brandon Holybee, Portland, OR (US); Kevin P. O'Brien, Portland, OR (US); Dmitri Evgenievich Nikonov, Beaverton, OR (US); John J. Plombon, Portland, OR (US); Ian Alexander Young, Olympia, WA (US); Raseong Kim, Portland, OR (US); Carly Rogan, North Plains, OR (US); Dominique A. Adams, Portland, OR (US); Arnab Sen Gupta, Hillsboro, OR (US); Marko Radosavljevic, Portland, OR (US); Scott B. Clendenning, Portland, OR (US); Gauri Auluck, Hillsboro, OR (US); Hai Li, Portland, OR (US); Matthew V. Metz, Portland, OR (US); Tristan A. Tronic, Aloha, OR (US); I-Cheng Tung, Hillsboro, OR (US)

(73) Assignee: Intel Corporation, Santa Clara, CA (US)

(21) Appl. No.: 17/947,071

(22) Filed: Sep. 16, 2022

(51) Int. Cl. H01L 29/78; H01L 29/51

(52) U.S. Cl. CPC H01L 29/78391; H01L 29/516

(57) ABSTRACT

In one embodiment, a transistor device includes a gate material layer on a substrate, a ferroelectric (FE) material layer on the gate material, a semiconductor channel material layer on the FE material layer, a first source/drain material on the FE material layer and adjacent the semiconductor channel material layer, and a second source/drain material on the FE material layer and adjacent the semiconductor channel material layer and on an opposite side of the semiconductor channel material layer from the first source/drain material. A first portion of the FE material layer is directly between the gate material and the first source/drain material, and a second portion of the FE material layer is directly between the gate material and the second source/drain material.

### BACKGROUND

As computing demand increases, corresponding energy demands increase exponentially. In this scenario, compute limitations may be defined not by the speed of operation, but by the energy needed for operation. To lower energy consumption in compute devices, transistor devices can be designed to use lower operating voltages. However, conventional metal oxide semiconductor field-effect transistor (MOSFET) devices encounter limits on their operating voltage, with their threshold voltage and subthreshold slope dictating the ability to lower currents in the off-state. Numerous efforts to lower the operating voltage of MOSFET devices have, at best, achieved as low as 0.6V, as further lowering of the supply voltage runs in to the device thresholds and results in a drastic decrease in the speed of the MOSFET operation. Ferroelectric field-effect transistor (FeFET) devices are another type of device that has been investigated for use in future compute devices.

### BRIEF DESCRIPTION OF THE DRAWINGS

FIG. 1 illustrates an example conventional FeFET device.

FIG. 2 illustrates an example FeFET device in accordance with embodiments herein.

FIGS. 3A-3B illustrate an example process of manufacturing the example FeFET of FIG. 2 in accordance with embodiments herein.

FIG. 4 illustrates another example FeFET device in accordance with embodiments herein.

FIG. 5 illustrates an example FeFET device in accordance with embodiments herein.

FIG. 6 illustrates another example FeFET device in accordance with embodiments herein.

FIGS. 7A-7B illustrate an example crystal lattice structure and a surface of iso-energy, respectively, of an example perovskite material.

FIGS. 8A-8B illustrate simulation results for a polarization evolution in a perovskite material when used in the example device of FIG. 6 based on the Landau-Khalatnikov equations.

FIG. 9 illustrates simulation results for the switching of the same perovskite material modeled in FIGS. 8A-8B.

FIG. 10 illustrates still another example FeFET device in accordance with embodiments herein.

FIG. 11 is a top view of a wafer and dies that may be included in a microelectronic assembly, in accordance with any of the embodiments disclosed herein.

FIG. 12 is a cross-sectional side view of an integrated circuit device that may be included in a microelectronic assembly, in accordance with any of the embodiments disclosed herein.

FIG. 13 is a cross-sectional side view of an integrated circuit device assembly that may include a microelectronic assembly, in accordance with any of the embodiments disclosed herein.

FIG. 14 is a block diagram of an example electrical device that may include a microelectronic assembly, in accordance with any of the embodiments disclosed herein.

### DETAILED DESCRIPTION

Embodiments herein describe ferroelectric field-effect transistor (FeFET) devices with the potential for lower operating or switching voltages. FeFETs, in contrast to MOSFETs, have the potential for switching with a steep subthreshold slope. Most current FeFET devices use HfZrO or similar materials in the gate, which require a high switching electric field (referred to as the “coercive field”). In many instances, these materials may require an approximately 1.5V supply voltage or higher. Perovskite ferroelectric (FE) materials, on the other hand, have a lower coercive field. However, they require a single-crystalline structures and their operation depends on the direction of the electric field relative to the crystal axes.

Certain embodiments herein may include FeFET structures with regions in which the gate and source/drain regions are each in direct contact with opposite sides of the FE material. For example, certain embodiments may utilize a channel layer that is of smaller length than the FE material layer. In these regions, a metal/FE/metal structure may be formed and thus, the polarization may be switched with a lower gate-to-source voltage, which may be approximately equal to or equal to the coercive voltage of the FE material. In certain embodiments, the length of the overall FE material layer may also be less than the FE domain size to ensure proper switching.

Further, certain embodiments herein may include FeFET structures that allow for a “tilted” electric field that takes advantage of this phenomena to allow for lower operating voltages. These structures may include, for example, an orientation of the gate and source/drain regions that causes an electric field in the FE material between the gate and source/drain regions to be non-vertical/tilted. The tilted electric field may aid in faster switching of the polarization of the FE material within the FeFET device, as described further below.

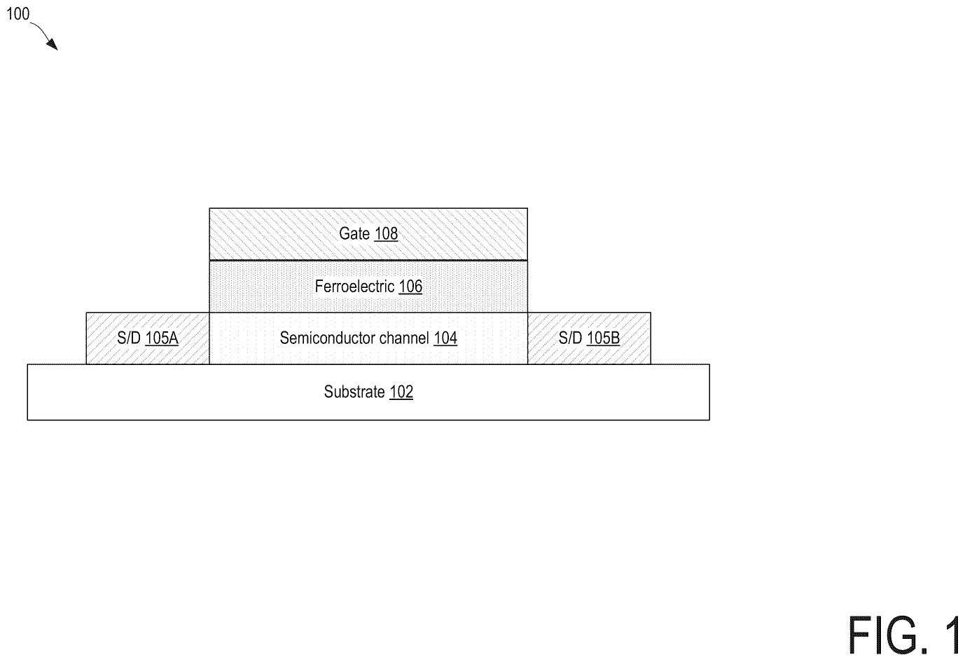

FIG. 1 illustrates an example conventional FeFET device 100. The example device 100 includes a substrate 102 with a semiconductor channel layer 104 formed on the substrate 102 and source/drain regions 105 adjacent the semiconductor layer 104 on either side. The device 100 also includes an FE material 106 on the semiconductor layer 104 and the source/drain regions 105, and a gate contact 108 on the FE material 106.

In operation, when a sufficiently large voltage is applied to the gate contact 108, the polarization direction in the FE material layer 106 may be switched. This induces a change in the charge in the channel within the semiconductor channel layer 104 and modulates the source-drain current of the device 100. Any voltage applied to the gate 108 in the device 100 drops across both the FE and semiconductor channel layers. However, only the fraction of the voltage that drops across the FE layer 106 is responsible for the switching of its polarization direction. Hence, the fraction of the gate voltage that is dropped across the semiconductor channel layer 104 is overhead and increases the overall energy consumption of the device.

Accordingly, certain embodiments herein may implement a channel layer with a length that is smaller than the length of the FE/gate oxide layer. For example, a device may include extended source/drain regions, portions of which are in contact with the FE layer directly. This results in a metal-FE-metal capacitor region under the source/drain extension, which can be switched at a much lower voltage. For a crystalline perovskite FE material in a metal/FE/metal type structure, the voltage required to switch its polarization, or its coercive voltage (V_{coercive}) can be designed to be ultra-low (e.g., less than 200 mV). Hence, polarization switching can be a super energy efficient process. This is one motivation for using such materials to make FeFET device structures in accordance with the present disclosure. Accordingly, certain embodiments may implement a novel FeFET stack/structure that reduces the required gate voltage swing of the FeFET by using a perovskite FE material, which can achieve lower operating voltages, and eliminating potential overhead caused by the additional voltage drop across the channel layer in the FeFET stack. This can lead to much greater energy efficiency in FeFET devices.

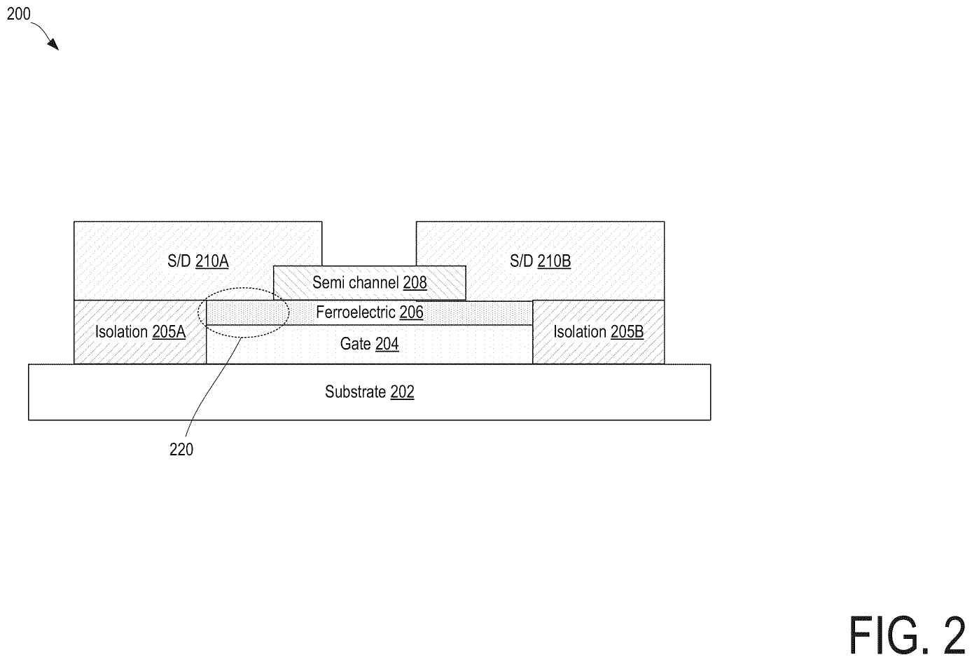

FIG. 2 illustrates an example FeFET device 200 in accordance with embodiments herein. The example device 200 is a bottom-gated device that includes a substrate 202 with a gate material 204 formed thereon and a FE material 206 formed on the gate material 204. The device 200 also includes isolation regions 205, e.g., dielectric material, formed on the substrate 202 and adjacent the gate 204 and the FE material 206. The device 200 also includes a semiconductor channel material 208 formed on the FE material 206, and source/drain regions 210 formed on and adjacent the semiconductor channel 208.

Example materials for use in the semiconductor channel layer 208 may include a doped BaSnO₃ (e.g., doped with La or other dopants such as neodymium (Nd)), doped SrTiO₃ (e.g., doped with La or other dopants such as Nd), IGZO (Indium Gallium Zinc Oxide), LaNiO₃, SrSnO₃, or (Ba—Sr)SnO₃, and example perovskite FE materials for use in FE layer 206 may include BaTiO₃, Ba(Zr—Ti)O₃, (Ba—Ca)TiO₃, (Ba—Sr)TiO₃, (Ba—Ca)(Ti—Zr)O₃, BiFeO₃, (Bi—La)FeO₃, Bi(Fe—Co)O₃, LiNbO₃, or KNbO₃. As used herein, (A-B) (e.g., La—Ba) may refer to elements A and B in proportions AₓB₍₁₋ₓ₎ (e.g., LaₓBa₍₁₋ₓ₎SnO₃). The substrate 202 may include an oxide template material, which may be lattice-matched to one or more of the materials grown thereon. For example, the substrate 202 may include an oxide material layer such as SrTiO₃, which may be on a SiO₂ or similar type of substrate material. Other embodiments may utilize a substrate 202 that includes DyScO₃ or GdScO₃. The gate material 204 and source/drain regions 210 may include SrRuO₃, (Sr—Ba)RuO₃, (La—Ba)SnO₃, (La—Sr)MnO₃, (La—Ba)CoO₃, LaNiO₃, LaRuO₃, YBa₂Cu₃O₇, SrVO₃, SrCoO₃, SrMoO₃, Pt, Ru, Ir, Pd, W, Mo, RuO₂, IrOx, or MoO₂.

In the structure shown in FIG. 2, the semiconductor channel layer 208 is of a smaller length that the FE layer 206. This results in regions where the source/drain regions 210 and the gate 204 are in direct contact with the two opposite sides of the FE layer (e.g., in the area 220 circled in FIG. 2), forming a metal/FE/metal structure. In this area 220, the FE polarization is switched at a low V_{GS} (=V_{coercive}). In particular, the entirety of the gate voltage (V_{GS}) drops across the FE layer 206; therefore, in this region (220), the FE polarization switches when V_{GS} reaches the coercive voltage of the FE layer 206 (V_{coercive}) To modulate the channel charge, the FE polarization below the channel layer 208 needs to be switched, and this is ensured in embodiments herein by having the total length of the FE layer 206 (i.e., the distance between the two isolation regions 205) be smaller than the FE domain size of the FE material used (i.e., L_{FElayer}<L_{FEdomain}). Due to collective switching of the FE order parameter, the polarization in the entirety of the FE layer 206, including in the region underneath the channel layer 208 is switched. With the total length of the FE layer 206 being less that the FE domain size, the polarization in the whole layer 206 (including under the semiconducting channel layer 208) switches in unison. Thus, desired modulation in the channel charge can be achieved, which in turn modulates the current flowing between the source/drain regions (I Ds).

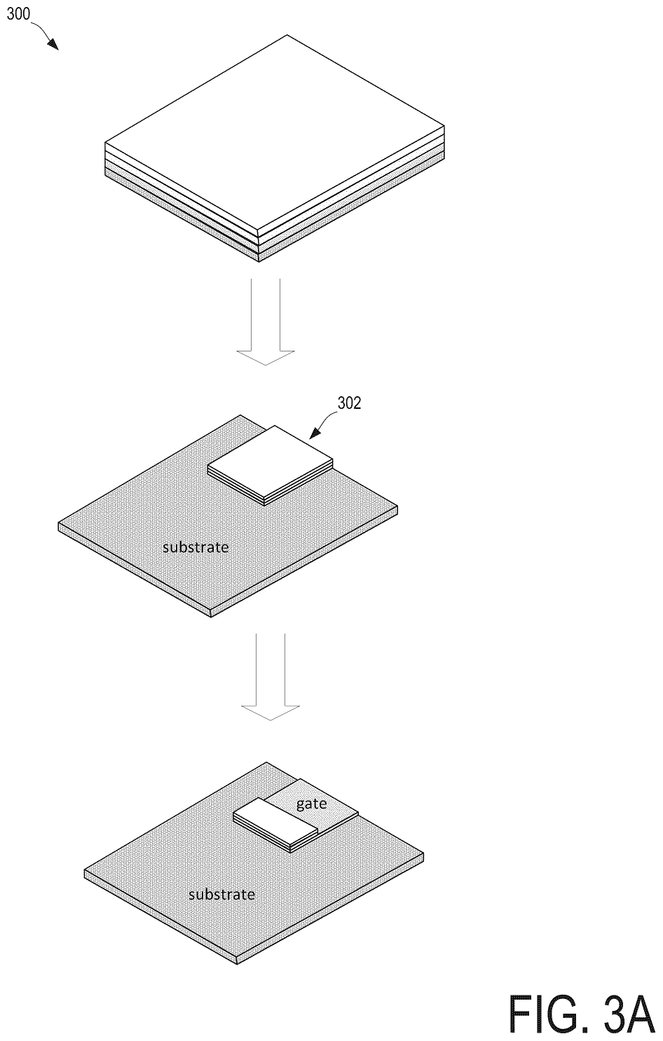

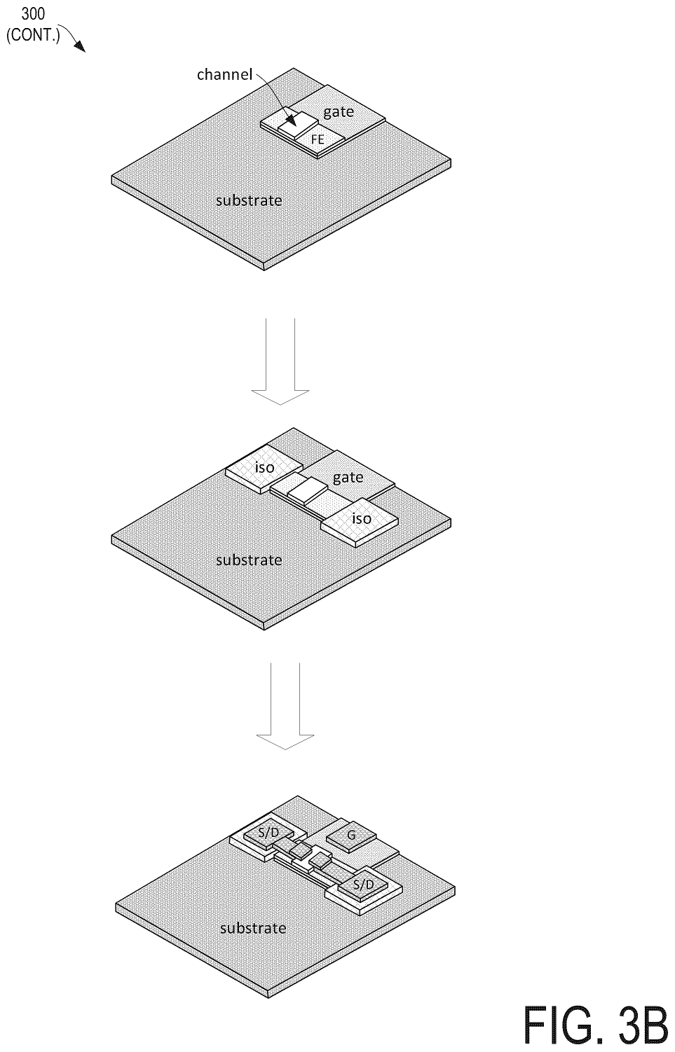

FIGS. 3A-3B illustrate an example process 300 of manufacturing a FeFET in accordance with embodiments herein. The example process shown may include additional, fewer, or different operations than those shown or described below. In some embodiments, one or more of the operations shown include multiple operations, sub-operations, etc. The example process 300 starts with the fabrication of the full stack that includes the substrate (e.g., 202), gate material layer (e.g., 204), FE material layer (e.g., 206), and semiconductor channel material layer (e.g., 208). The stack is then etched to define isolated device regions (e.g., 302, which includes the gate, FE material, and channel portion of a device). While one device region is shown in FIG. 3A, it will be understood the process applies to fabrication of multiple FeFET devices at a time (e.g., on a wafer), and may include etching to define multiple device regions. Next, the FE material layer and channel layer are etched to open access for the bottom gate material as shown in the bottom illustration of FIG. 3A, and then the channel layer is further etched to reduce its length compared with the FE material layer as shown in the top illustration of FIG. 3B. Then, isolation regions (e.g., 205) are formed on either side of the device region 302, i.e., adjacent each side of the remaining FE material and gate layers, and the source/drain regions (e.g., 210) are formed on the isolation regions as shown in the bottom illustration of FIG. 3B. In addition, a contact layer may be formed on the gate material as shown.

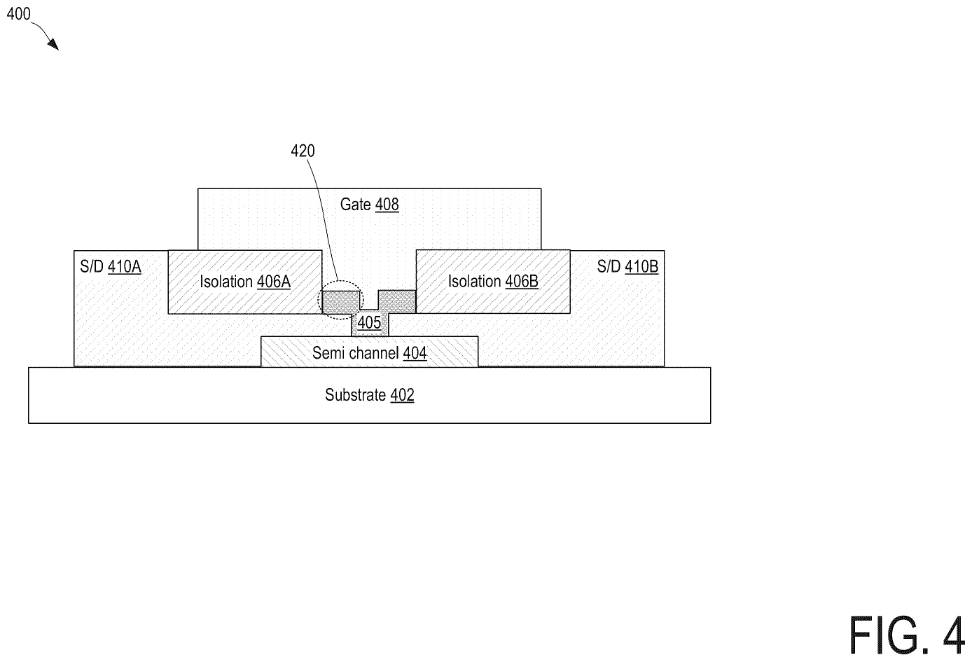

FIG. 4 illustrates another example FeFET device 400 in accordance with embodiments herein. The example device 400 is a top-gated device that includes a substrate 402 with a semiconductor channel material layer 404 formed thereon and source/drain regions 410 formed on and adjacent the semiconductor channel material layer 404 on either side. The device 400 also includes an FE material layer 405 formed on the semiconductor channel 404 and on portions of the source/drain regions 410 that are on the semiconductor channel layer 404 as shown (i.e., with a portion of the FE material being on the semiconductor channel layer 404 and between the respective source/drain regions 410). The device 400 also includes isolation regions 406 (e.g., dielectric materials) formed on a portion of the source/drain regions 410 and adjacent the portion of the FE material layer 405 that is on the source/drain regions 410. The isolation regions 406 act to electrically isolate the source/drain regions 410 from the gate material 408 that is formed on the FE material layer 405 and on portions of the isolation regions 406. The materials used for each respective material/layer may be the same as described above with respect to the device 200 of FIG. 2.

The example device 400 may be formed as follows. First, the channel layer 404 may be patterned on the substrate 402, followed by the source/drain region 410 formation. Next, the FE material layer 405 may be deposited and patterned. The isolation regions 406 may be formed next, with the top gate material 408 being formed last. The example device 400 includes regions (420) where the gate material 408, the FE material 405, and the source/drain material 410 forms a metal/FE/metal like structure in a similar manner as the bottom gated device shown in FIG. 2. This region 420 may allow for low voltage switching in the same manner as that described above with respect to FIG. 2.

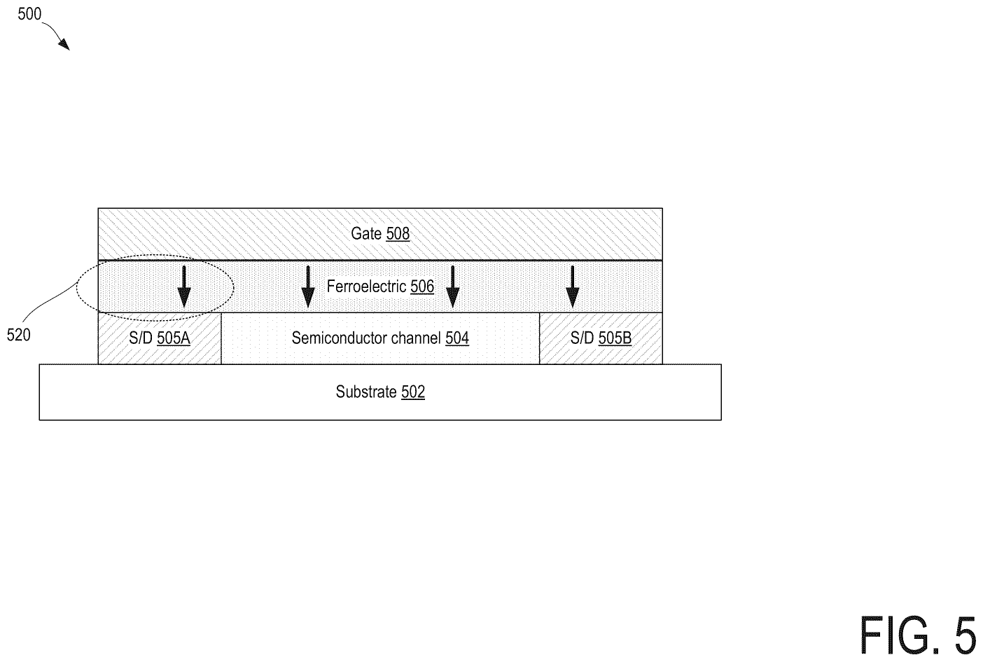

FIG. 5 illustrates an example FeFET device 500 in accordance with embodiments herein. The device includes a substrate 502 with a semiconductor channel material 504 formed thereon and source/drain regions 505 adjacent the semiconductor material 504 on either side, an FE material 506 on the semiconductor material 504 (and on the source/drain regions 505), and a gate material 508 on the FE material 506. The materials used for each respective material/layer may be the same as described above with respect to the device 200 of FIG. 2.

The example device 500 is formed similar to the device 100, but includes regions (520) where the gate material 508, the FE material 506, and the source/drain materials 505 form a metal/FE/metal-like structure similar to those described above. Thus, it may allow for low voltage switching in the same manner as described above.

In operation, a voltage applied to the gate 508 will cause an electric field that is generally vertical across the FE material 506 as shown. However, with the use of certain FE materials (e.g., perovskite materials), a vertical electric field such as the one shown may require higher gate voltages to cause a switching of the polarization of the FE material 506. Certain embodiments herein allow for further reduction in the switching voltage required by implementing a design that allows for a non-vertical/tilted electric field within the FE material layer 506.

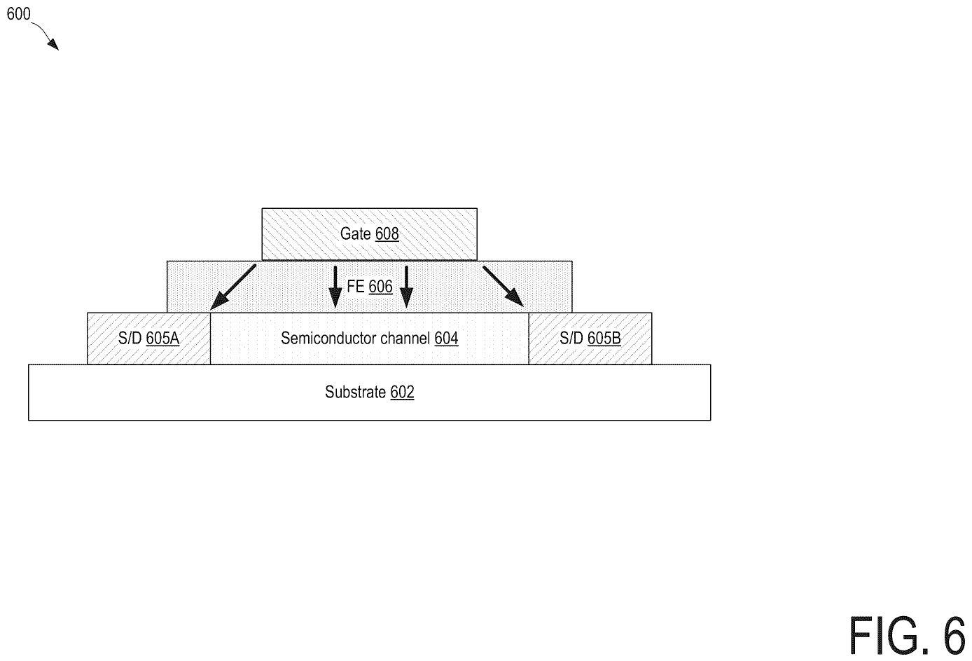

FIG. 6 illustrates an example FeFET device 600 in accordance with embodiments herein. The example device 600 is formed similar to the device 500, and includes a substrate 602 with a semiconductor channel material 604 formed thereon and source/drain regions 605 adjacent the semiconductor material 604 on either side, an FE material 606 on the semiconductor material 604 (and on the source/drain regions 605), and a gate material 608 on the FE material 606. The materials used for each respective material/layer may be the same as described above with respect to the device 200 of FIG. 2.

The device 600 contrasts with the device 100 in that the length of the gate is smaller than the length of the semiconductor material 604 and the FE material 606 (i.e., a length of contact between the FE material layer 606 and the gate material layer 608 is less than the length of contact between the semiconductor channel material layer 604 and the FE material layer 606), which causes a tilted/non-vertical electric field within the ferroelectric (FE) material 606 when a voltage is applied to the gate as shown. This tilted electric field may allow for lower polarization switching voltages to be used with the device 600 as compared with the device 100, e.g., for reasons described further below. While certain areas of the FE material (e.g., the center area over the semiconductor channel 604) may not encounter the same tilted field (e.g., at the edges of the FE material 606), the polarization of the FE material 606 will switch in accordance with the lowest switching voltage. That is, a voltage that will cause the polarization to switch at the edge of the FE material 606, which may be lower because of the tilted electric field, will still cause the polarization switching even though the other areas of the FE material do not encounter the same tilted electric field.

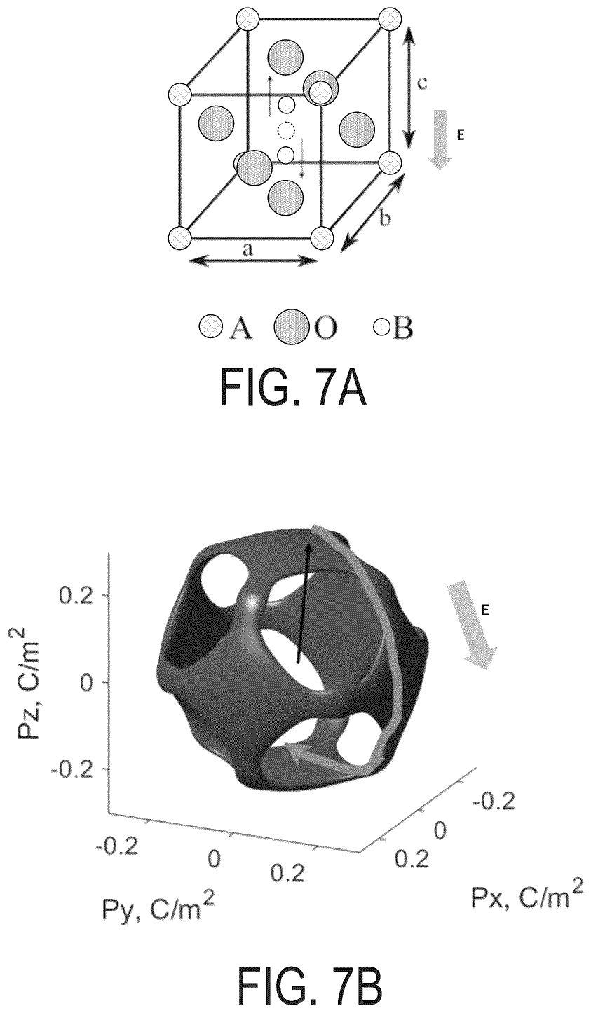

FIGS. 7A-7B illustrate an example crystal lattice structure and a surface of iso-energy, respectively, of an example perovskite material. The example perovskite material is modeled as ABO₃, where A represents a first element of the perovskite material (e.g., Barium), B represents a second element of the perovskite material (e.g., Titanium), and 0 represents Oxygen in the material. In the example shown in FIG. 7A, the direction of an applied electric field is shown by a block arrow, and a shift in the B material/ion from the center of the lattice structure corresponds to the ferroelectric polarization (indicated by the smaller line arrows in FIG. 7A). In the example shown in FIG. 7B, the direction of an applied electric field is shown again by a block arrow (tilted in the example shown), while the trajectory of switching of the polarization of the material is shown by the curved arrow. It is seen from the example shown that the polarization switching trajectory is curved along the iso-energy surface.

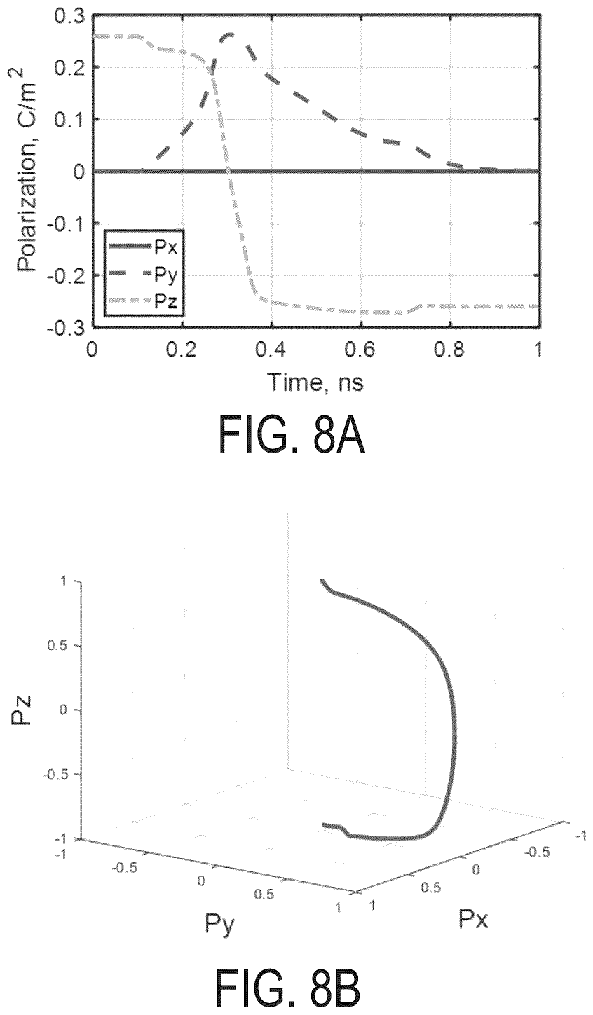

FIGS. 8A-8B illustrate simulation results for a polarization evolution in a perovskite material (e.g., BaTiO₃) when used in the example device 600 of FIG. 6 based on the Landau-Khalatnikov equations. In particular, FIG. 8A illustrates projections of polarization on the x-, y-, and z-axes vs. time, while FIG. 8B illustrates the trajectory of the FE polarization (in units of the saturated polarization, Ps) in the space of its projections on the x-, y-, and z-axes. As shown by the figures, the direction of polarization switches from an initial state with only a (positive) z-component to a final state with only a (negative) z-component, while having a y-component in the time in between. A tilted electric field can aid in switching at lower voltages because of this y-component that occurs between the switched states, i.e., the tilted field may be able to contribute along the y-component.

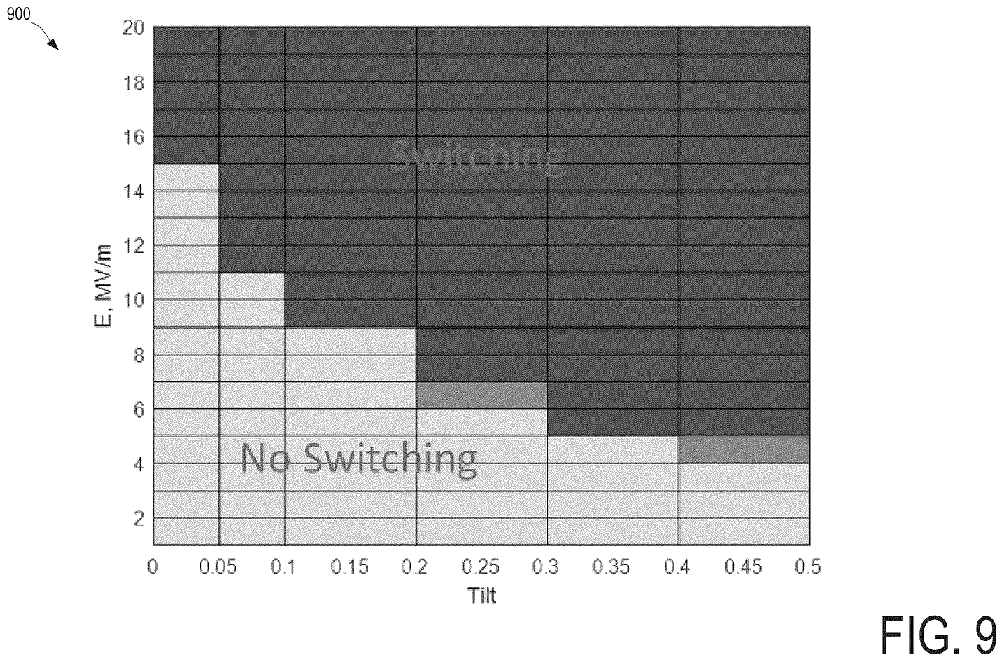

FIG. 9 illustrates simulation results for the switching of the same perovskite material modeled in FIGS. 8A-8B. In particular, FIG. 9 illustrates a chart 900 showing a dependence of an applied switching field on the degree of tilt of the field. The x-axis indicates the tilt of an applied field on the material (measured as ratio of the x-projection to the z-projection of the electric field), the y-axis indicates an applied field voltage in MV/m (Megavolts per meter), and certain regions within the chart indicate whether there is polarization switching with the combination of applied field (y-axis) and tilt (x-axis). It will be seen that at certain applied voltages (e.g., 10 MV/m), the polarization may switch at higher tilts but not at lower tilts. Thus, an FeFET device that causes a tilted electric field (e.g., as shown in FIG. 6), even though it may occur only over a portion of the FE material of an FeFET device, may be advantageous to allow for lowering the switching voltage of the device as compared with a conventional FeFET structure (e.g., the one shown in FIG. 1).

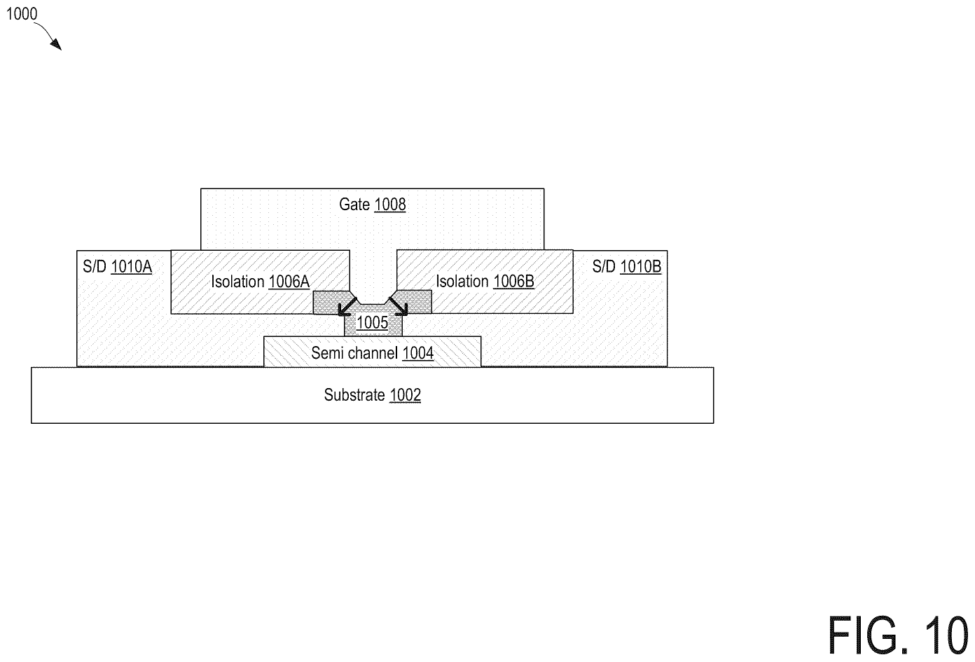

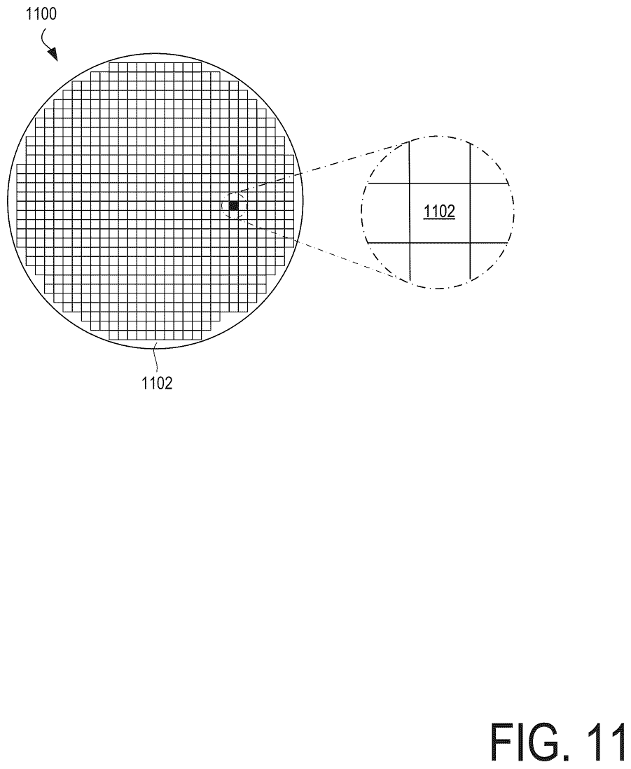

FIG. 10 illustrates still another example FeFET device 1000 in accordance with embodiments herein. The device 1000 includes a semiconductor channel material layer 1004 formed thereon and source/drain regions 1010 formed on and adjacent the semiconductor channel material layer 1004 on either side. The device 1000 also includes an FE material layer 1005 formed on the semiconductor channel 1004 and on portions of the source/drain regions 1010 that are on the semiconductor channel layer 1004 as shown (i.e., with a portion of the FE material being on the semiconductor channel layer 1004 and between the respective source/drain regions 1010). The device 1000 also includes isolation regions 1006 (e.g., dielectric materials) formed on a portion of the source/drain regions 1010 and adjacent the portion of the FE material layer 1005 that is on the source/drain regions 1010. The isolation regions 1006 act to electrically isolate the source/drain regions 1010 from the gate material 1008 that is formed on the FE material layer 1005 and on portions of the isolation regions 1006. The materials used for each respective material/layer may be the same as described above with respect to the device 200 of FIG. 2.

While the example device 1000 is formed similar to the device 400 of FIG. 4, it contrasts from the device 400 in that it includes wider isolation regions 1006 (relative to the isolation regions 406 of the device 400) that are formed partially on the FE material 1005. Constructed in this way, the device 1000 may allow for a tilted electric field between the gate 1008 and the source/drain regions 1010 (as shown by the tilted arrows), similar to the device 600 of FIG. 6, allowing for further lowered switching voltages than those seen by the device 400. In certain embodiments, the device 200 of FIG. 2 may similarly be modified to implement a tilted electric field between its gate and source/drain regions.

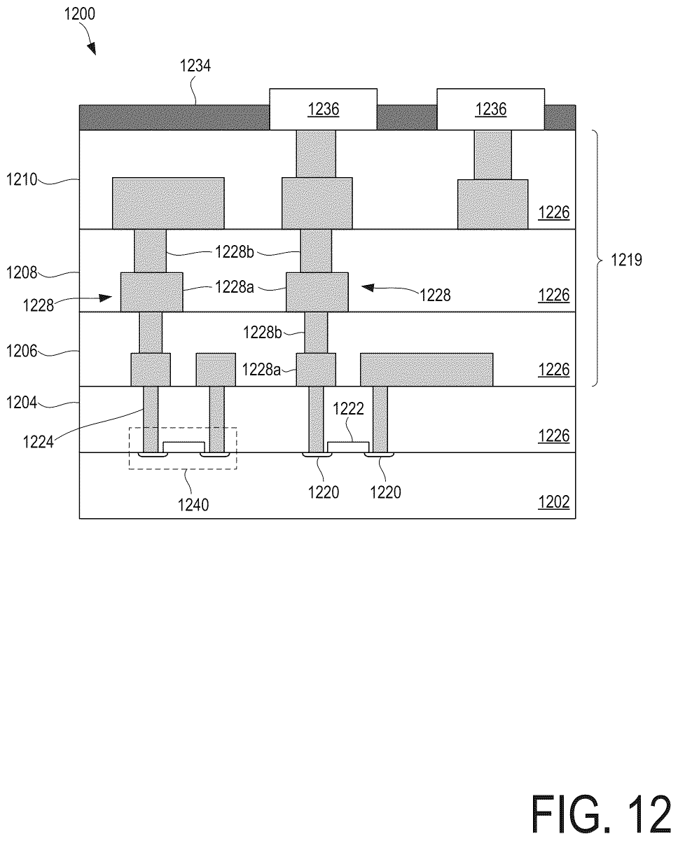

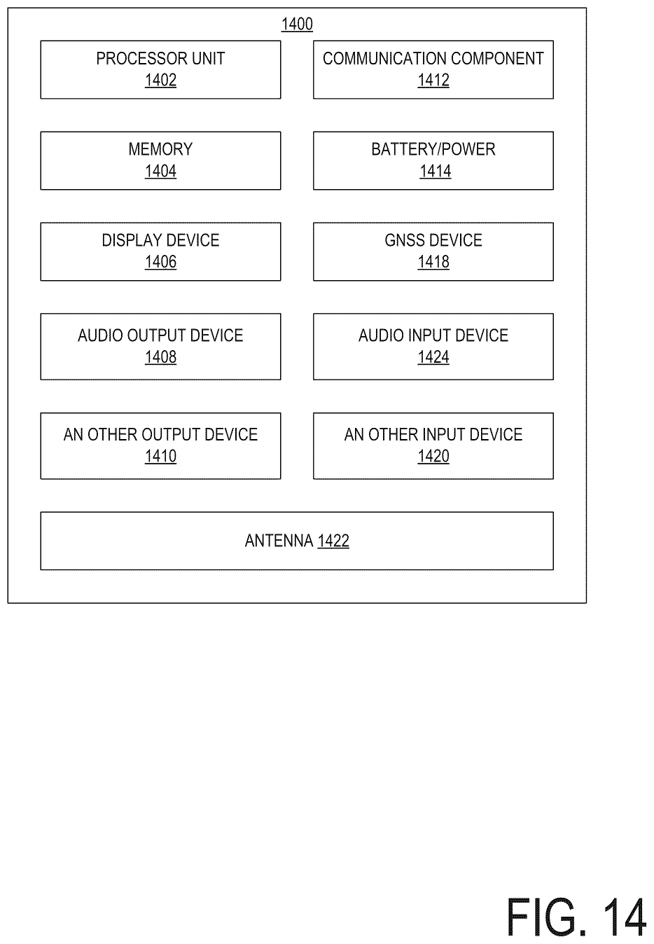

FIG. 11 is a top view of a wafer 1100 and dies 1102 that may incorporate any of the embodiments disclosed herein. The wafer 1100 may be composed of semiconductor material and may include one or more dies 1102 having integrated circuit structures formed on a surface of the wafer 1100. The individual dies 1102 may be a repeating unit of an integrated circuit product that includes any suitable integrated circuit. After the fabrication of the semiconductor product is complete, the wafer 1100 may undergo a singulation process in which the dies 1102 are separated from one another to provide discrete “chips” of the integrated circuit product. The die 1102 may include one or more transistors (e.g., some of the transistors 1240 of FIG. 12, discussed below), supporting circuitry to route electrical signals to the transistors, passive components (e.g., signal traces, resistors, capacitors, or inductors), and/or any other integrated circuit components. In some embodiments, the wafer 1100 or the die 1102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1102. For example, a memory array formed by multiple memory devices may be formed on a same die 1102 as a processor unit (e.g., the processor unit 1402 of FIG. 14) or other logic that is configured to store information in the memory devices or execute instructions stored in the memory array.

FIG. 12 is a cross-sectional side view of an integrated circuit device 1200 that may be included in any of the embodiments disclosed herein. One or more of the integrated circuit devices 1200 may be included in one or more dies 1102 (FIG. 11). The integrated circuit device 1200 may be formed on a die substrate 1202 (e.g., the wafer 1100 of FIG. 11) and may be included in a die (e.g., the die 1102 of FIG. 11). The die substrate 1202 may be a semiconductor substrate composed of semiconductor material systems including, for example, n-type or p-type materials systems (or a combination of both). The die substrate 1202 may include, for example, a crystalline substrate formed using a bulk silicon or a silicon-on-insulator (SOI) substructure. In some embodiments, the die substrate 1202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an integrated circuit device 1200 may be used. The die substrate 1202 may be part of a singulated die (e.g., the dies 1102 of FIG. 11) or a wafer (e.g., the wafer 1100 of FIG. 11).

The integrated circuit device 1200 may include one or more device layers 1204 disposed on the die substrate 1202. The device layer 1204 may include features of one or more transistors 1240 (e.g., metal oxide semiconductor field-effect transistors (MOSFETs)) formed on the die substrate 1202. The transistors 1240 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 12, a transistor 1240 may include a gate 1222 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1240 along the source-channel-drain direction, the gate electrode may consist of a U-shaped structure that includes a bottom portion substantially parallel to the surface of the die substrate 1202 and two sidewall portions that are substantially perpendicular to the top surface of the die substrate 1202. In other embodiments, at least one of the metal layers that form the gate electrode may simply be a planar layer that is substantially parallel to the top surface of the die substrate 1202 and does not include sidewall portions substantially perpendicular to the top surface of the die substrate 1202. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of individual transistors 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1220 may be formed using one or more alternate semiconductor materials such as germanium or a group III-V material or alloy. In further embodiments, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the integrated circuit device 1200.

The interconnect structures 1228 may be arranged within the interconnect layers 1206-1210 to route electrical signals according to a wide variety of designs; in particular, the arrangement is not limited to the particular configuration of interconnect structures 1228 depicted in FIG. 12. Although a particular number of interconnect layers 1206-1210 is depicted in FIG. 12, embodiments of the present disclosure include integrated circuit devices having more or fewer interconnect layers than depicted.

In some embodiments, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page and/or in a direction across the page from the perspective of FIG. 12. The vias 1228b may be arranged to route electrical signals in a direction of a plane that is substantially perpendicular to the surface of the die substrate 1202 upon which the device layer 1204 is formed. In some embodiments, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some embodiments, dielectric material 1226 disposed between the interconnect structures 1228 in different ones of the interconnect layers 1206-1210 may have different compositions; in other embodiments, the composition of the dielectric material 1226 between different interconnect layers 1206-1210 may be the same. The device layer 1204 may include a dielectric material 1226 disposed between the transistors 1240 and a bottom layer of the metallization stack as well. The dielectric material 1226 included in the device layer 1204 may have a different composition than the dielectric material 1226 included in the interconnect layers 1206-1210; in other embodiments, the composition of the dielectric material 1226 in the device layer 1204 may be the same as a dielectric material 1226 included in any one of the interconnect layers 1206-1210.

A first interconnect layer 1206 (referred to as Metal 1 or “M1”) may be formed directly on the device layer 1204. In some embodiments, the first interconnect layer 1206 may include lines 1228a and/or vias 1228b, as shown. The lines 1228a of the first interconnect layer 1206 may be coupled with contacts (e.g., the S/D contacts 1224) of the device layer 1204. The vias 1228b of the first interconnect layer 1206 may be coupled with the lines 1228a of a second interconnect layer 1208.

The second interconnect layer 1208 (referred to as Metal 2 or “M2”) may be formed directly on the first interconnect layer 1206. In some embodiments, the second interconnect layer 1208 may include via 1228b to couple the lines 1228 of the second interconnect layer 1208 with the lines 1228a of a third interconnect layer 1210. Although the lines 1228a and the vias 1228b are structurally delineated with a line within individual interconnect layers for the sake of clarity, the lines 1228a and the vias 1228b may be structurally and/or materially contiguous (e.g., simultaneously filled during a dual-damascene process) in some embodiments.

The third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206. In some embodiments, the interconnect layers that are “higher up” in the metallization stack 1219 in the integrated circuit device 1200 (i.e., farther away from the device layer 1204) may be thicker that the interconnect layers that are lower in the metallization stack 1219, with lines 1228a and vias 1228b in the higher interconnect layers being thicker than those in the lower interconnect layers.

The integrated circuit device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to external devices. For example, solder bonds may be formed on the one or more conductive contacts 1236 to mechanically and/or electrically couple an integrated circuit die including the integrated circuit device 1200 with another component (e.g., a printed circuit board). The integrated circuit device 1200 may include additional or alternate structures to route the electrical signals from the interconnect layers 1206-1210; for example, the conductive contacts 1236 may include other analogous features (e.g., posts) that route the electrical signals to external components.

In some embodiments in which the integrated circuit device 1200 is a double-sided die, the integrated circuit device 1200 may include another metallization stack (not shown) on the opposite side of the device layer(s) 1204. This metallization stack may include multiple interconnect layers as discussed above with reference to the interconnect layers 1206-1210, to provide conductive pathways (e.g., including conductive lines and vias) between the device layer(s) 1204 and additional conductive contacts (not shown) on the opposite side of the integrated circuit device 1200 from the conductive contacts 1236.

In other embodiments in which the integrated circuit device 1200 is a double-sided die, the integrated circuit device 1200 may include one or more through silicon vias (TSVs) through the die substrate 1202; these TSVs may make contact with the device layer(s) 1204, and may provide conductive pathways between the device layer(s) 1204 and additional conductive contacts (not shown) on the opposite side of the integrated circuit device 1200 from the conductive contacts 1236. In some embodiments, TSVs extending through the substrate can be used for routing power and ground signals from conductive contacts on the opposite side of the integrated circuit device 1200 from the conductive contacts 1236 to the transistors 1240 and any other components integrated into the die 1200, and the metallization stack 1219 can be used to route I/O signals from the conductive contacts 1236 to transistors 1240 and any other components integrated into the die 1200.

Multiple integrated circuit devices 1200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

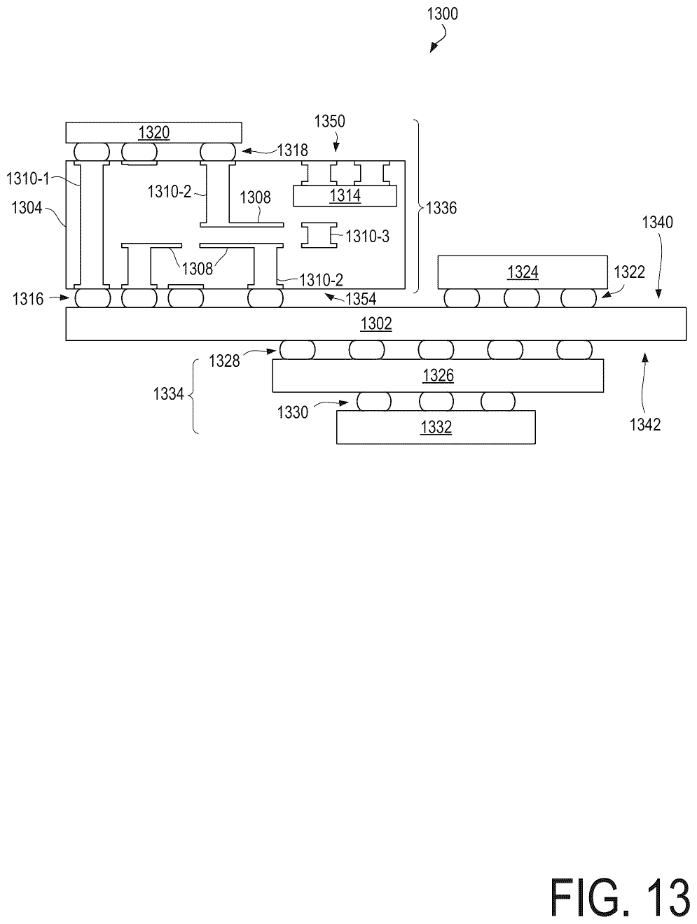

FIG. 13 is a cross-sectional side view of an integrated circuit device assembly 1300 that may include any of the embodiments disclosed herein. The integrated circuit device assembly 1300 includes a number of components disposed on a circuit board 1302 (which may be a motherboard, system board, mainboard, etc.). The integrated circuit device assembly 1300 includes components disposed on a first face 1340 of the circuit board 1302 and an opposing second face 1342 of the circuit board 1302; generally, components may be disposed on one or both faces 1340 and 1342.

In some embodiments, the circuit board 1302 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1302. In other embodiments, the circuit board 1302 may be a non-PCB substrate. The integrated circuit device assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1336 may include an integrated circuit component 1320 coupled to an interposer 1304 by coupling components 1318. The coupling components 1318 may take any suitable form for the application, such as the forms discussed above with reference to the coupling components 1316. Although a single integrated circuit component 1320 is shown in FIG. 13, multiple integrated circuit components may be coupled to the interposer 1304; indeed, additional interposers may be coupled to the interposer 1304. The interposer 1304 may provide an intervening substrate used to bridge the circuit board 1302 and the integrated circuit component 1320.

The integrated circuit component 1320 may be a packaged or unpacked integrated circuit product that includes one or more integrated circuit dies (e.g., the die 1102 of FIG. 11, the integrated circuit device 1200 of FIG. 12) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1320, a single monolithic integrated circuit die comprises solder bumps attached to contacts on the die. The solder bumps allow the die to be directly attached to the interposer 1304. The integrated circuit component 1320 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1320 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1320 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1320 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1304 may spread connections to a wider pitch or reroute a connection to a different connection. For example, the interposer 1304 may couple the integrated circuit component 1320 to a set of ball grid array (BGA) conductive contacts of the coupling components 1316 for coupling to the circuit board 1302. In the embodiment illustrated in FIG. 13, the integrated circuit component 1320 and the circuit board 1302 are attached to opposing sides of the interposer 1304; in other embodiments, the integrated circuit component 1320 and the circuit board 1302 may be attached to a same side of the interposer 1304. In some embodiments, three or more components may be interconnected by way of the interposer 1304.

In some embodiments, the interposer 1304 may be formed as a PCB, including multiple metal layers separated from one another by layers of dielectric material and interconnected by electrically conductive vias. In some embodiments, the interposer 1304 may be formed of an epoxy resin, a fiberglass-reinforced epoxy resin, an epoxy resin with inorganic fillers, a ceramic material, or a polymer material such as polyimide. In some embodiments, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through hole vias 1310-1 (that extend from a first face 1350 of the interposer 1304 to a second face 1354 of the interposer 1304), blind vias 1310-2 (that extend from the first or second faces 1350 or 1354 of the interposer 1304 to an internal metal layer), and buried vias 1310-3 (that connect internal metal layers).

In some embodiments, the interposer 1304 can comprise a silicon interposer. Through silicon vias (TSV) extending through the silicon interposer can connect connections on a first face of a silicon interposer to an opposing second face of the silicon interposer. In some embodiments, an interposer 1304 comprising a silicon interposer can further comprise one or more routing layers to route connections on a first face of the interposer 1304 to an opposing second face of the interposer 1304.

The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art. In embodiments where the interposer is a non-printed circuit board

The integrated circuit device assembly 1300 may include an integrated circuit component 1324 coupled to the first face 1340 of the circuit board 1302 by coupling components 1322. The coupling components 1322 may take the form of any of the embodiments discussed above with reference to the coupling components 1316, and the integrated circuit component 1324 may take the form of any of the embodiments discussed above with reference to the integrated circuit component 1320.

The integrated circuit device assembly 1300 illustrated in FIG. 13 includes a package-on-package structure 1334 coupled to the second face 1342 of the circuit board 1302 by coupling components 1328. The package-on-package structure 1334 may include an integrated circuit component 1326 and an integrated circuit component 1332 coupled together by coupling components 1330 such that the integrated circuit component 1326 is disposed between the circuit board 1302 and the integrated circuit component 1332. The coupling components 1328 and 1330 may take the form of any of the embodiments of the coupling components 1316 discussed above, and the integrated circuit components 1326 and 1332 may take the form of any of the embodiments of the integrated circuit component 1320 discussed above. The package-on-package structure 1334 may be configured in accordance with any of the package-on-package structures known in the art.

FIG. 14 is a block diagram of an example electrical device 1400 that may include one or more of the embodiments disclosed herein. For example, any suitable ones of the components of the electrical device 1400 may include one or more of the integrated circuit device assemblies 1300, integrated circuit components 1320, integrated circuit devices 1200, or integrated circuit dies 1102 disclosed herein. A number of components are illustrated in FIG. 14 as included in the electrical device 1400, but any one or more of these components may be omitted or duplicated, as suitable for the application. In some embodiments, some or all of the components included in the electrical device 1400 may be attached to one or more motherboards mainboards, or system boards. In some embodiments, one or more of these components are fabricated onto a single system-on-a-chip (SoC) die.

Additionally, in various embodiments, the electrical device 1400 may not include one or more of the components illustrated in FIG. 14, but the electrical device 1400 may include interface circuitry for coupling to the one or more components. For example, the electrical device 1400 may not include a display device 1406, but may include display device interface circuitry (e.g., a connector and driver circuitry) to which a display device 1406 may be coupled. In another set of examples, the electrical device 1400 may not include an audio input device 1424 or an audio output device 1408, but may include audio input or output device interface circuitry (e.g., connectors and supporting circuitry) to which an audio input device 1424 or audio output device 1408 may be coupled.

The electrical device 1400 may include one or more processor units 1402 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1402 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1400 may include a memory 1404, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1404 may include memory that is located on the same integrated circuit die as the processor unit 1402. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1400 can comprise one or more processor units 1402 that are heterogeneous or asymmetric to another processor unit 1402 in the electrical device 1400. There can be a variety of differences between the processing units 1402 in a system in terms of a spectrum of metrics of merit including architectural, microarchitectural, thermal, power consumption characteristics, and the like. These differences can effectively manifest themselves as asymmetry and heterogeneity among the processor units 1402 in the electrical device 1400.

In some embodiments, the electrical device 1400 may include a communication component 1412 (e.g., one or more communication components). For example, the communication component 1412 can manage wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1412 may operate in accordance with other wireless protocols in other embodiments. The electrical device 1400 may include an antenna 1422 to facilitate wireless communications and/or to receive other wireless communications (such as AM or FM radio transmissions).

In some embodiments, the communication component 1412 may manage wired communications, such as electrical, optical, or any other suitable communication protocols (e.g., IEEE 802.3 Ethernet standards). As noted above, the communication component 1412 may include multiple communication components. For instance, a first communication component 1412 may be dedicated to shorter-range wireless communications such as Wi-Fi or Bluetooth, and a second communication component 1412 may be dedicated to longer-range wireless communications such as global positioning system (GPS), EDGE, GPRS, CDMA, WiMAX, LTE, EV-DO, or others. In some embodiments, a first communication component 1412 may be dedicated to wireless communications, and a second communication component 1412 may be dedicated to wired communications.

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display device 1406 (or corresponding interface circuitry, as discussed above). The display device 1406 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any embedded or wired or wirelessly connected external device that generates an audible indicator, such speakers, headsets, or earbuds.

The electrical device 1400 may include an audio input device 1424 (or corresponding interface circuitry, as discussed above). The audio input device 1424 may include any embedded or wired or wirelessly connected device that generates a signal representative of a sound, such as microphones, microphone arrays, or digital instruments (e.g., instruments having a musical instrument digital interface (MIDI) output). The electrical device 1400 may include a Global Navigation Satellite System (GNSS) device 1418 (or corresponding interface circuitry, as discussed above), such as a Global Positioning System (GPS) device. The GNSS device 1418 may be in communication with a satellite-based system and may determine a geolocation of the electrical device 1400 based on information received from one or more GNSS satellites, as known in the art.

The electrical device 1400 may include an other output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include another input device 1420 (or corresponding interface circuitry, as discussed above). Examples of the other input device 1420 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1400 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1400 may be any other electronic device that processes data. In some embodiments, the electrical device 1400 may comprise multiple discrete physical components. Given the range of devices that the electrical device 1400 can be manifested as in various embodiments, in some embodiments, the electrical device 1400 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is a transistor device comprising: a substrate; a gate material on the substrate; a ferroelectric (FE) material layer on the gate material; a semiconductor channel material layer on the FE material layer; a first source/drain material on the FE material layer and adjacent the semiconductor channel material layer; and a second source/drain material on the FE material layer and adjacent the semiconductor channel material layer and on an opposite side of the semiconductor channel material layer from the first source/drain material; wherein a first portion of the FE material layer is directly between the gate material and the first source/drain material, and a second portion of the FE material layer is directly between the gate material and the second source/drain material.

Example 2 includes the subject matter of Example 1, wherein the semiconductor material layer has a length that is less than a length of the FE material layer.

Example 3 includes the subject matter of Example 1 or 2, wherein the first source/drain material is further on a first portion of the semiconductor channel material layer, and the second source/drain material is further on a second portion of the semiconductor channel material layer.

Example 4 includes the subject matter of any one of Examples 1-3, further comprising: a first dielectric material on the substrate and adjacent the gate material layer and the FE material layer; and a second dielectric material on the substrate and adjacent the gate material layer and the FE material layer, wherein the second dielectric material is on an opposite side of the gate material layer and the FE material layer as the first dielectric material.

Example 5 includes the subject matter of any one of Examples 1-4, wherein the FE material layer includes a perovskite material.

Example 6 includes the subject matter of any one of Examples 1-5, wherein the FE material layer includes one or more of Barium, Titanium, Zirconium, Calcium, Strontium, Lanthanum, Bismuth, Iron, Cobalt, Lithium, Niobium, Potassium, and Oxygen.

Example 7 includes the subject matter of any one of Examples 1-6, wherein the semiconductor channel material layer includes one or more of Barium, Tin, Lanthanum, Neodymium, Strontium, Titanium, Indium, Gallium, Zinc, Nickel, and Oxygen.

Example 8 includes the subject matter of any one of Examples 1-7, wherein the first source/drain material and the second source/drain material each comprise one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

Example 9 includes the subject matter of any one of Examples 1-8, wherein the substrate comprises one or more of Strontium, Titanium, Dysprosium, Gadolinium, Scandium, and Oxygen.

Example 10 is a transistor device comprising: a substrate; a semiconductor channel material layer on the substrate; a first source/drain material on a first side of the semiconductor channel material layer; a second source/drain material on a second side of the semiconductor channel material layer opposite the first side; a ferroelectric (FE) material layer on the semiconductor channel material layer and between the first source/drain material and the second source/drain material; and a gate material on the FE material layer; wherein a first portion of the FE material layer is directly between the gate material and the first source/drain material, and a second portion of the FE material layer is directly between the gate material and the second source/drain material.

Example 11 includes the subject matter of Example 10, wherein the FE material is further on the first source/drain material, and further on the second source/drain material.

Example 12 includes the subject matter of Example 10 or 11, further comprising: a first dielectric material on the first source/drain material, wherein a portion of the first source/drain material is between the first dielectric material and the semiconductor channel material layer; and a second dielectric material on the second source/drain material, wherein a portion of the second source/drain material is between the second dielectric material and the semiconductor channel material layer.

Example 13 includes the subject matter of Example 12, wherein the gate material is further on the first dielectric material and the second dielectric material, the first dielectric material is between the gate material and the first source/drain material, and the second dielectric material is between the gate material and the second source/drain material.

Example 14 includes the subject matter of any one of Examples 12-13, wherein the first dielectric material is further on a portion of the FE material that is on the first source/drain material, and the second dielectric material is further on a portion of the FE material that is on the second source/drain material.

Example 15 includes the subject matter of any one of Examples 10-14, wherein the FE material layer includes a perovskite material.

Example 16 includes the subject matter of any one of Examples 10-15, wherein the FE material layer includes one or more of Barium, Titanium, Zirconium, Calcium, Strontium, Lanthanum, Bismuth, Iron, Cobalt, Lithium, Niobium, Potassium, and Oxygen.

Example 17 includes the subject matter of any one of Examples 10-16, wherein the semiconductor channel material layer includes one or more of Barium, Tin, Lanthanum, Neodymium, Strontium, Titanium, Indium, Gallium, Zinc, Nickel, and Oxygen.

Example 18 includes the subject matter of any one of Examples 10-17, wherein the first source/drain material and the second source/drain material each comprise one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

Example 19 includes the subject matter of any one of Examples 10-18, wherein the substrate comprises one or more of Strontium, Titanium, Dysprosium, Gadolinium, Scandium, and Oxygen.

Example 20 is a transistor device comprising: a substrate; a semiconductor channel material layer on the substrate; a first source/drain material on the substrate adjacent the semiconductor material layer; a second source/drain material on the substrate adjacent the semiconductor material layer and on an opposite side of the semiconductor channel material layer from the first source/drain material; a ferroelectric (FE) material layer on the semiconductor channel material layer; and a gate material on the FE material layer, wherein a length of contact between the semiconductor channel material layer and the FE material layer is less than a length of contact between the FE material layer and the gate material.

Example 21 includes the subject matter of Example 20, wherein the FE material is further on a portion of the first source/drain material and on a portion of the second source/drain material.

Example 22 includes the subject matter of Example 20 or 21, wherein the first source/drain material is further on a portion of the semiconductor channel material layer, the second source/drain material is further on a portion of the semiconductor channel material layer, and a portion of the FE material layer is between the first source/drain material and the second source/drain material.

Example 23 includes the subject matter of any one of Examples 20-22, wherein the FE material layer includes a perovskite material.

Example 24 includes the subject matter of any one of Examples 20-23, wherein the FE material layer includes one or more of Barium, Titanium, Zirconium, Calcium, Strontium, Lanthanum, Bismuth, Iron, Cobalt, Lithium, Niobium, Potassium, and Oxygen.

Example 25 includes the subject matter of any one of Examples 20-24, wherein the semiconductor channel material layer includes one or more of Barium, Tin, Lanthanum, Neodymium, Strontium, Titanium, Indium, Gallium, Zinc, Nickel, and Oxygen.

Example 26 includes the subject matter of any one of Examples 20-25, wherein the first source/drain material and the second source/drain material each comprise one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

Example 27 includes the subject matter of any one of Examples 20-26, wherein the substrate comprises one or more of Strontium, Titanium, Dysprosium, Gadolinium, Scandium, and Oxygen.

Example 28 is an integrated circuit die comprising a plurality of transistor device according to any one of Examples 1-27.

Example 29 is an integrated circuit device comprising an integrated circuit die coupled to a package substrate, the integrated circuit die comprising a plurality of transistor device according to any one of Examples 1-27.

Example 30 is a system comprising a main board and an integrated circuit device coupled to the main board, the integrated circuit device comprising a plurality of transistor device according to any one of Examples 1-27.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. A transistor device comprising:
a substrate;
a gate material on the substrate;
a ferroelectric (FE) material layer on the gate material;
a semiconductor channel material layer on the FE material layer;
a first source/drain material on the FE material layer and adjacent the semiconductor channel material layer; and
a second source/drain material on the FE material layer and adjacent the semiconductor channel material layer and on an opposite side of the semiconductor channel material layer from the first source/drain material;
wherein a first portion of the FE material layer is directly between the gate material and the first source/drain material, and a second portion of the FE material layer is directly between the gate material and the second source/drain material.

2. The device of claim 1, wherein the semiconductor material layer has a length that is less than a length of the FE material layer.

3. The device of claim 1, wherein the first source/drain material is further on a first portion of the semiconductor channel material layer, and the second source/drain material is further on a second portion of the semiconductor channel material layer.

4. The device of claim 1, further comprising:
a first dielectric material on the substrate and adjacent the gate material layer and the FE material layer; and
a second dielectric material on the substrate and adjacent the gate material layer and the FE material layer, wherein the second dielectric material is on an opposite side of the gate material layer and the FE material layer as the first dielectric material.

5. The device of claim 1, wherein the FE material layer includes a perovskite material.

6. The device of claim 1, wherein the FE material layer includes one or more of Barium, Titanium, Zirconium, Calcium, Strontium, Lanthanum, Bismuth, Iron, Cobalt, Lithium, Niobium, Potassium, and Oxygen.

7. The device of claim 1, wherein the semiconductor channel material layer includes one or more of Barium, Tin, Lanthanum, Neodymium, Strontium, Titanium, Indium, Gallium, Zinc, Nickel, and Oxygen.

8. The device of claim 1, wherein the first source/drain material and the second source/drain material each comprise one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

9. The device of claim 1, wherein the substrate comprises one or more of Strontium, Titanium, Dysprosium, Gadolinium, Scandium, and Oxygen.

10. A transistor device comprising:
a substrate;
a semiconductor channel material layer on the substrate;
a first source/drain material on a first side of the semiconductor channel material layer;
a second source/drain material on a second side of the semiconductor channel material layer opposite the first side;
a ferroelectric (FE) material layer on the semiconductor channel material layer and between the first source/drain material and the second source/drain material; and
a gate material on the FE material layer;
wherein a first portion of the FE material layer is directly between the gate material and the first source/drain material, and a second portion of the FE material layer is directly between the gate material and the second source/drain material.

11. The device of claim 10, wherein the FE material is further on the first source/drain material, and further on the second source/drain material.

12. The device of claim 10, further comprising:
a first dielectric material on the first source/drain material, wherein a portion of the first source/drain material is between the first dielectric material and the semiconductor channel material layer; and
a second dielectric material on the second source/drain material, wherein a portion of the second source/drain material is between the second dielectric material and the semiconductor channel material layer.

13. The device of claim 12, wherein the gate material is further on the first dielectric material and the second dielectric material, the first dielectric material is between the gate material and the first source/drain material, and the second dielectric material is between the gate material and the second source/drain material.

14. The device of claim 12, wherein the first dielectric material is further on a portion of the FE material that is on the first source/drain material, and the second dielectric material is further on a portion of the FE material that is on the second source/drain material.

15. The device of claim 10, wherein the FE material layer includes a perovskite material.

16. The device of claim 10, wherein the FE material layer includes one or more of Barium, Titanium, Zirconium, Calcium, Strontium, Lanthanum, Bismuth, Iron, Cobalt, Lithium, Niobium, Potassium, and Oxygen.

17. The device of claim 10, wherein the semiconductor channel material layer includes one or more of Barium, Tin, Lanthanum, Neodymium, Strontium, Titanium, Indium, Gallium, Zinc, Nickel, and Oxygen.

18. The device of claim 10, wherein the first source/drain material and the second source/drain material each comprise one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

19. A transistor device comprising:
a substrate;
a semiconductor channel material layer on the substrate;
a first source/drain material on the substrate adjacent the semiconductor material layer;
a second source/drain material on the substrate adjacent the semiconductor material layer and on an opposite side of the semiconductor channel material layer from the first source/drain material;
a ferroelectric (FE) material layer on the semiconductor channel material layer; and
a gate material on the FE material layer, wherein a length of contact between the semiconductor channel material layer and the FE material layer is less than a length of contact between the FE material layer and the gate material.

20. The device of claim 19, wherein the FE material is further on a portion of the first source/drain material and on a portion of the second source/drain material.

21. The device of claim 19, wherein the first source/drain material is further on a portion of the semiconductor channel material layer, the second source/drain material is further on a portion of the semiconductor channel material layer, and a portion of the FE material layer is between the first source/drain material and the second source/drain material.

22. The device of claim 19, wherein the FE material layer includes a perovskite material.

23. The device of claim 19, wherein the FE material layer includes one or more of Barium, Titanium, Zirconium, Calcium, Strontium, Lanthanum, Bismuth, Iron, Cobalt, Lithium, Niobium, Potassium, and Oxygen.

24. The device of claim 19, wherein the semiconductor channel material layer includes one or more of Barium, Tin, Lanthanum, Neodymium, Strontium, Titanium, Indium, Gallium, Zinc, Nickel, and Oxygen.

25. The device of claim 19, wherein the first source/drain material and the second source/drain material each comprise one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.
